(19) United States
(12) Patent Application Publication
(10) Pub. No.: US 2002/0084450 A1
(43) Pub. Date: Jul. 4, 2002

(54) Semiconductor device and method for fabricating a semiconductor device

(76) Inventor: Ihl Hyun Cho, Daejeon (KR)

Correspondence Address: PILLSBURY WINTHROP, LLP, P.O. BOX 10500, MCLEAN, VA, 22102, US

(21) Appl. No.: 10/026,537

(22) Filed: Dec. 27, 2001

(30) Foreign Application Priority Data
Dec. 29, 2000 (KR) 2000-85583

(51) Int. Cl. H01L 47/00

(52) U.S. Cl. 257/1

(57) ABSTRACT

Disclosed is a semiconductor device having a gate structure comprising a gate oxide layer formed on a semiconductor substrate, a conductive layer formed on the gate oxide layer, and a metal oxide layer formed at the interface between the gate oxide layer and the conductive layer, thereby forming a metal oxide layer having a high-k dielectric constant to produce a gate structure having stable electrical parametrics and improved functional performance.

### BACKGROUND OF THE INVENTION

1. Field of the Invention

The present invention relates to a semiconductor device and a method of fabricating such devices to produce next generation semiconductor products that are able to provide low power consumption and high performance.

2. Description of the Related Art

Generally, the gate of a semiconductor device is formed by forming a gate insulating layer, depositing a gate conductive layer on the gate insulating layer, and then patterning and etching the stacked layers. In many conventional devices, the gate insulating layer is a silicon oxide layer formed by oxidizing the silicon substrate and the gate conductive layer is a doped polysilicon layer deposited on the silicon oxide layer.

As semiconductor devices are produced with increasingly high integration densities, the critical dimensions of the gate structures is being correspondingly reduced. Thus, it is becoming increasingly difficult to utilize the traditional polysilicon and silicon oxide layers as the gate conductive and gate insulating layers.

In particular, in order to meet the requirements of high-density semiconductor devices, the thickness of the silicon oxide layer must be decreased to such a degree that the resulting devices experience increased leakage current resulting from direct-tunneling effects.

Moreover, the polysilicon layer traditionally used as a gate material contains impurities necessary to reduce resistance, but which, in combination with narrower gate widths, results in increased frequency of gate depletion problems.

When a silicon oxide layer is used as a gate insulating layer and a polysilicon layer is used as a gate material in highly integrated devices, therefore, the gate threshold voltage becomes unstable as a result of the increased leakage current and gate depletion. Hence, characteristics of the resulting semiconductor device are degraded and the performance and reliability become unsatisfactory.

In order to overcome these disadvantages and limitations, many efforts have been made to suppress the leakage current due resulting from the direct tunneling effects by using a high-k dielectric layer, i.e., one in which the dielectric constant is at least twice that of a silicon oxide layer, and to remove the gate depletion by replacing polysilicon in the gate electrode with a metal layer.

A semiconductor device and a method of fabricating such devices according to a more recent prior art process to suppress the gate depletion problems is explained below with reference to FIGS. 1-3.

FIGS. 1-3 illustrate cross-sectional views of a process for fabricating a semiconductor device using a high-k dielectric layer and a metal gate according to a prior art manufacturing process.

Referring to FIG. 1, a silicon nitride layer 3 is deposited on a semiconductor substrate 1, preferably silicon, to prevent oxidation of the substrate.

A high-k dielectric layer 5 is then formed on the silicon nitride layer 3. The high-k dielectric layer 5 is then crystallized and, after crystallization, is thermally treated using N₂O and NO gas to remove impurities such as carbon (C), hydrocarbons, water and other impurities and thereby reduce leakage current generation.

Referring to FIG. 2, a metal nitride layer 7, which acts as a diffusion barrier layer, is then deposited on the crystallized and thermally treated high-k dielectric layer Sa. A metal layer 9 for forming a gate conductor is then deposited on the metal nitride layer 7.

Referring to FIG. 3, a gate structure 11 is then formed by patterning and etching the metal layer 9, metal nitride layer 7, crystallized high-k dielectric layer 5a, and silicon nitride layer 3. The remaining portions of the etched layers being designated in FIG. 3 as 9a, 7a, 5b, and 3a respectively.

An oxide layer 13 is then formed on both sidewalls of the gate structure 11 to suppress plasma damage caused during the etch step.

A light ion implantation is then performed into an active area of the semiconductor substrate 1 adjacent the gate structure 11 to suppress the generation of hot carriers. Spacers 15 are then formed on both sidewalls of the gate structure 11. Source/drain regions 8a and 8b of the semiconductor device are formed by performing a high dose ion implant into the substrate adjacent the gate structure 11 and outside the spacers 15. Unfortunately, semiconductor devices produced according to this prior art method have a number of disadvantages and limitations.

The method of fabricating a semiconductor device according to the prior art method illustrated in FIGS. 1-3 is more complex and difficult than the traditional method of forming a gate structure of only a silicon oxide layer and a polysilicon layer.

Moreover, as shown in FIG. 1, when thermal treatment is carried out to crystallize the high-k dielectric layer, a silicon oxide layer having a low dielectric constant is formed at the interface between the semiconductor substrate and the dielectric layer, thereby reducing the overall dielectric constant.

Further, both the defect density and the surface roughness at the interface between the high-k dielectric layer and semiconductor substrate are generally inferior to the levels typically found between the silicon oxide layer and the substrate of the traditional method, thereby greatly degrading the device characteristics and operational capability.

### SUMMARY OF THE INVENTION

Accordingly, the present invention is directed to semiconductor device, and a method for fabricating such devices, that substantially eliminates one or more of the limitations and disadvantages of the prior art devices and methods.

The object of the present invention is to provide a semiconductor device, and method for fabricating such devices, that provides a device exhibiting sufficiently low power consumption and high device performance to be suitable for next generation semiconductor devices.

Additional features and advantages of the invention will be set forth in the following description and, in part, will be apparent from the description, or may be learned by practicing the invention. The objectives and other advantages of the invention will be realized and attained by the structure particularly described in the written description and claims, as well as, the references drawings.

To achieve these and other advantages, and in accordance with the purpose of the present invention as embodied and broadly described, a semiconductor device according to the present invention comprises a gate oxide layer on a semiconductor substrate, a conductive metal layer on the gate oxide layer, and a metal oxide layer between the gate oxide layer and the conductive metal layer.

Another aspect of the invention is a method for fabricating a semiconductor device comprising the steps of growing a silicon oxide layer on a semiconductor substrate, forming a conductive layer on the silicon oxide layer, and forming a metal oxide layer at the interface between the silicon oxide layer and the conductive layer by carrying out a thermal treatment.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIGS. 1-3 illustrate cross-sectional views of the fabrication of a semiconductor device according to a conventional prior art method;

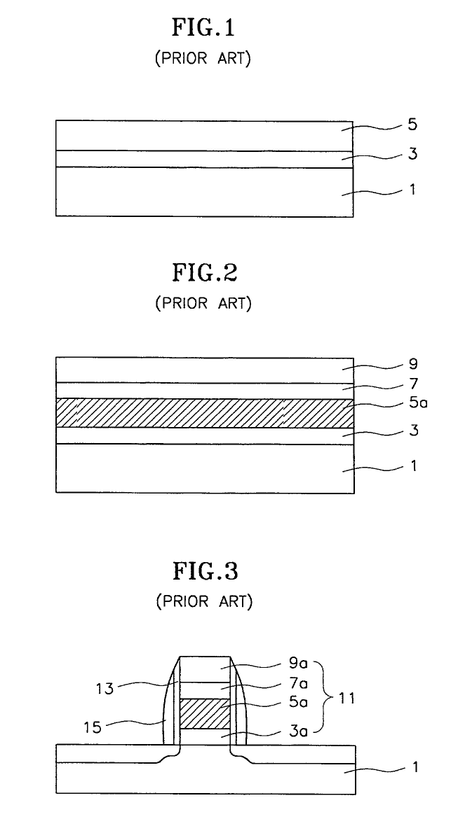

FIGS. 4-6 illustrate cross-sectional views of the fabrication of a semiconductor device according to the present invention;

FIG. 7 illustrates a cross-sectional view of a semiconductor device formed using the method illustrated in FIGS. 4-6 after additional processing;

FIG. 8 and FIG. 9 are TEM pictures of structures according to a preferred embodiment of the present invention both before and after thermal treatment of the wafer;

FIGS. 10(a)-(c) illustrate data attained by secondary ion mass spectroscopy (SIMS) of a structure formed according to a preferred embodiment of the present invention; and

FIGS. 11(a)-(b) illustrate the concentration distribution of a metal oxide layer on thermal treatment by XPS according to a preferred embodiment of the present invention.

### DETAILED DESCRIPTION OF THE PREFERRED EMBODIMENTS

Reference will now be made in detail to the preferred embodiments of the present invention, examples of which are illustrated in the accompanying drawings. Where possible, the same reference numerals will be used to identify similar or corresponding elements throughout the specification.

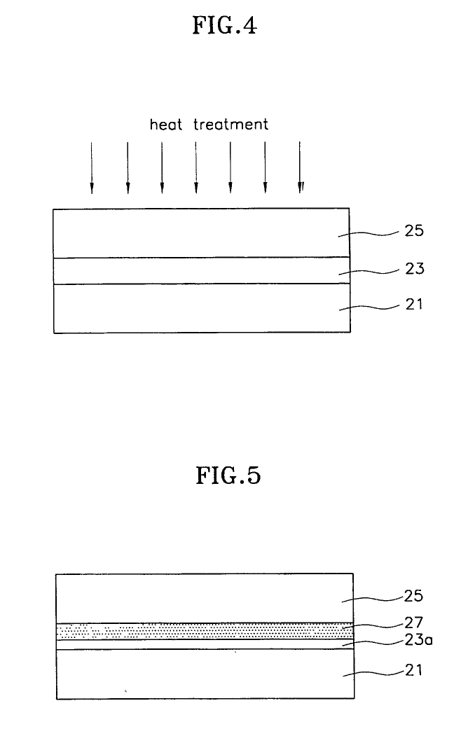

Referring to FIG. 4, a gate oxide layer, preferably a silicon oxide layer 23, is grown on a semiconductor substrate 21. In this case, the silicon oxide layer 23 is preferably grown to a thickness of 10 to 100 Å thick at a high temperature.

A gate conductive layer 25 is then deposited on the silicon oxide layer 23. In this case, the gate conductive layer 25 may be formed from either a metal layer or a metal nitride layer. Preferably, the gate conductive layer 25 is formed from a tungsten (W), tantalum (Ta), titanium (Ti), or aluminum (Al) layer. The gate conductive layer 25 may optionally be formed from a nitridated layer of the metal layer. The gate conductive layer 25 is preferably deposited to a thickness of 100 to 2000 Å.

Referring to FIG. 5, a thermal treatment is then applied to the water to accelerate the reaction between atoms at and near the interface between the silicon oxide layer 23 and the gate conductive layer 25 to form a metal oxide layer 27 having a dielectric constant of at least 3.9.

Thus, the thermal treatment enables metal atoms of the gate conductive layer 25 to react with oxygen atoms from the silicon oxide layer 23, thereby oxidizing at least a portion of the gate conductive layer 25. As a result of the oxidation, the thicknesses of both the silicon oxide layer 23 and the gate conductive layer 25 are reduced as they are consumed to form the metal oxide layer 27.

Moreover, it is possible to control the thickness of the metal oxide layer 27 formed by controlling and adjusting the reaction temperature, the reaction time, the thickness of the silicon oxide layer, the thickness and composition of the gate conductive layer and the like. Depending on the conditions and thicknesses used, it is possible to consume the silicon oxide layer 23 entirely or only partially during the formation of metal oxide layer 27.

The thermal treatment is preferably performed at or below atmospheric pressure and at a temperature of 500 to 1000° C. Further, the thermal treatment is preferably conducted under a gas ambient, with the gas being at least one of nitrogen, argon, and helium.

Referring to FIG. 6, a gate structure 29 for a semiconductor device is formed by patterning and etching a predetermined portion of the stacked structure after the metal oxide layer 27 has been formed.

Subsequently, a re-oxidation process is performed to suppress plasma damage generated during the etch step and thereby form an oxidation layer 31 on both sidewalls of the gate structure.

A typical LDD (lightly doped drain) process is then carried out on the resulting structure by lightly implanting impurity ions into the semiconductor substrate 21 adjacent the oxidation layers 31 at the sidewalls of the gate structure 29. Spacers 33 are then formed on the gate oxidation layers 31 at both sidewalls of the gate structure 29. Source/drain regions 35a and 35b are then formed by performing a heavy impurity ion implantation into the semiconductor substrate 21 adjacent both of the spacers 33. The formation of the source/drain regions essentially completes the basic transistor structure for a semiconductor device.

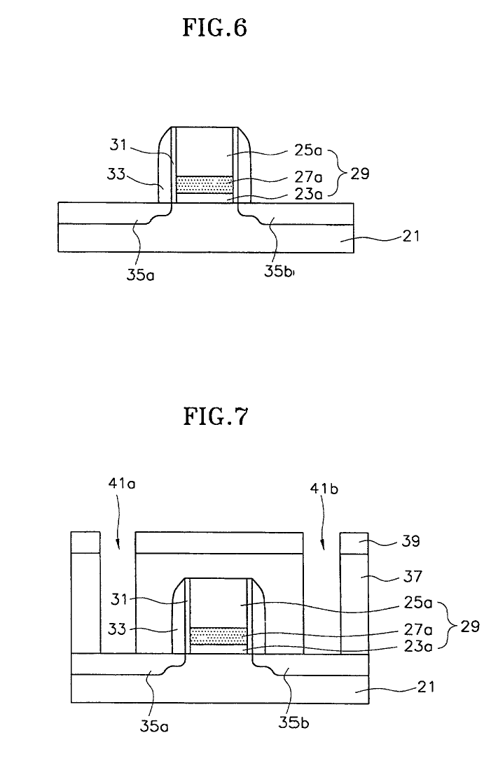

FIG. 7 illustrates a cross-sectional view of a semiconductor device formed using the method of fabricating a semiconductor device illustrated in FIGS. 4-6.

After forming the basic transistor structure illustrated in FIG. 6, an insulating interlayer 37 is formed on the surface of the resulting structure. Contact holes 41a and 41b, exposing source/drain regions 35a and 35b respectively, are formed by etching the insulating interlayer 37 using a photoresist pattern layer 39 as a mask. In general, the contact holes 41a and 41b will be formed simultaneously and will typically provide either a bitline contact or a storage electrode contact.

Although not shown in the drawing, metal lines, such as a bit line or a storage electrode line in a memory device are then formed to establish electrical contact to the source/drain regions 35a and 35b through the corresponding contact holes 41a and 41b.

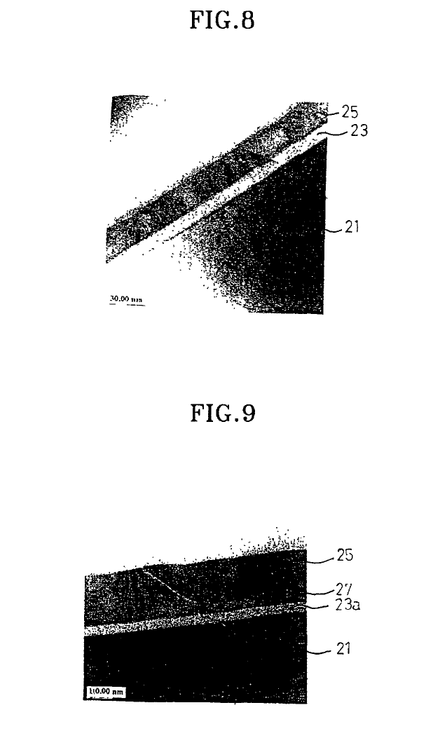

Experimental data relating to devices having the above structure that were manufactured according to a preferred embodiment of the present method is described with reference to FIGS. 8-11(b).

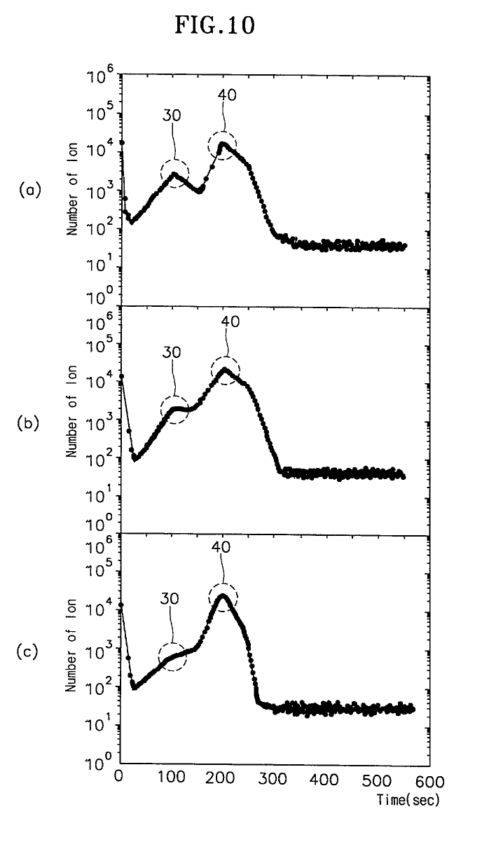

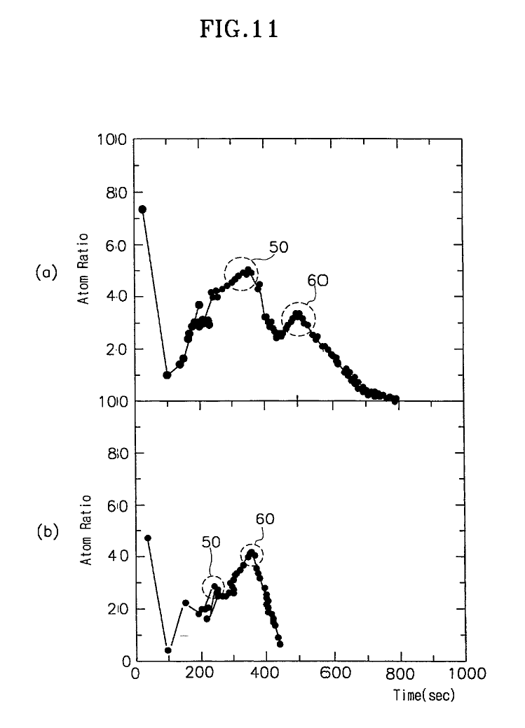

FIG. 8 and FIG. 9 illustrate TEM (Transmission Electron Microscope) micrographs of the stacked layer structure before and after thermal treatment. FIGS. 10(a)-(c) illustrate data attained by secondary ion mass spectroscopy (SIMS), and FIGS. 11(a)-(b) illustrate the oxygen concentration distribution detected by XPS (X-ray Photoelectron Spectroscopy) of a metal oxide layer after thermal treatment. For each of the devices tested in FIGS. 10(a)-11(b), a Ti layer was used as the gate conductive layer 25 in accord with a preferred embodiment of the present invention.

FIG. 8 is a TEM micrograph showing a cross-section of a wafer on which a silicon oxide layer 23 and a gate conductive layer 25 are formed on a semiconductor substrate 21.

FIG. 9 is another TEM micrograph of a wafer similar to the wafer shown in FIG. 8 after the thermal treatment has been completed to form the metal oxide layer. As shown in FIG. 9, a new metal oxide layer 27 has been formed at the interface between the gate conductive layer 25 and the silicon oxide layer 23.

The physical properties of the new metal oxide layers 27 as shown in FIG. 9 where then examined using secondary ion mass spectroscopy (SIMS) as follows.

FIG. 10(a) illustrates the oxygen profile of a wafer as shown in FIG. 8 is subjected to a thermal treatment process at a temperature of 750° C. in a nitrogen ambient. As shown in FIG. 8, the wafer includes a semiconductor substrate 21 on which a silicon oxide layer 23 and a gate conductive layer 25 have been formed. In FIG. 10(a), the X-axis designates the sputtering time in seconds and the Y-axis designates the number of ions detected, respectively.

Referring to FIG. 10(a), there are two peaks in the oxygen content. In this case, the first peak value 30a is seen after a sputtering time of approximately 100 seconds correlates to the titanium oxide (TiO₂) layer. The second peak value 40a correlates to the silicon oxide (SiO₂) layer.

FIG. 10(b) is similar to FIG. 10(a), but illustrates a profile obtained from a wafer that was subjected to a thermal treatment process at a temperature of 850° C., again under a nitrogen ambient. Referring to FIG. 10(b), this treatment produced a wafer having a first oxygen peak value 30b that is lower in intensity than the peak value 30a reflected in FIG. 10(a).

FIG. 10(c) illustrates a profile obtained from a wafer that had been subjected to a thermal treatment process at a temperature of 950° C., again under a nitrogen ambient. Referring to FIG. 10(c), this treatment produced a wafer having a first oxygen peak value 30c that is lower in intensity than the oxygen peak values 30a and 30b of the data reflected in FIGS. 10(a) and 10(b) for the other wafers.

A comparison of these three profiles demonstrates that when the thermal treatment process is conducted at temperatures over 750° C., the intensity of the peak value of the titanium oxide layer is reduced, apparently by transformation of the titanium oxide (TiO₂) layer into a titanium silicon (TiSi₂) layer.

FIG. 11(a) and FIG. 11(b) illustrate profiles attained by carrying out a thermal treatment process at temperatures of 750° C. and 950° C. respectively, under a nitrogen ambient. In FIGS. 11(a) and 11(b) the X-axis designates the sputtering time in seconds and the Y-axis designates an atomic ratio of oxygen present in the material under test.

Referring to FIG. 11(a), there are two peak values 50a and 60a of the oxygen atomic ratio, which correspond to the SIMS analysis illustrated in FIG. 10(a).

Moreover, it is apparent that the peak value 50a of oxygen atom ratio in FIG. 11(a) is higher than that of atom oxygen peak value 50b in FIG. 11(b).

Both the SIMS and XPS data clearly indicate that in the preferred embodiment of the present invention the new metal material layer formed at the interface between the silicon oxide layer 23 and the gate conductive layer 25 is a metal oxide layer 27. And further, the data demonstrates that the concentration of the metal oxide layer is reduced as the thermal treatment temperature increases above 750° C.

As mentioned in the above description, a gate structure in a semiconductor device formed according to the present invention has certain advantages or effects.

A semiconductor device and a fabricating method thereof according to the present invention reduces the leakage current by forming a metal oxide layer having a high-k dielectric constant between a silicon oxide layer and a gate conductive layer, suitable for use in high density, a low-power-consumption devices having critical dimensions under 0.15 μm.

Moreover, the present invention allows the thickness of the gate silicon oxide layer to be controlled while providing lower numbers of defect and reduced roughness at the interface between the semiconductor substrate and the silicon oxide layer.

Further, the present invention uses a metal or metal nitride layer as a gate conductive layer, thereby preventing or substantially suppressing degraded performance associated with the gate depletion problems.

Accordingly, the present invention provide a dielectric having an improved dielectric constant, improved operation capability, a simplified manufacturing process and reduced product cost as a result of a reduced number of process steps.

The foregoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

We claim:

1. A semiconductor device comprising:
a gate oxide layer on a semiconductor substrate;
a conductive layer on the gate oxide layer; and
a metal oxide layer at an interface between the gate oxide layer and the conductive layer.

2. The semiconductor device according to claim 1, wherein the gate oxide layer is a silicon oxide layer.

3. The semiconductor device according to claim 1, wherein the gate oxide layer has a thickness of 10 to 100 Å.

4. The semiconductor device according to claim 1, wherein the conductive layer comprises a conductive material selected from a group consisting of metals and metal nitrides.

5. The semiconductor device according to claim 4, wherein the conductive layer comprises at least one metal selected from a group consisting of tungsten, tantalum, titanium, and aluminum.

6. The semiconductor device according to claim 4, wherein the conductive layer comprises at least one metal nitride selected from a group consisting of tungsten nitride (WN), tantalum nitride (TaN), titanium nitride (TiN) and aluminum nitride (AlN).

7. The semiconductor device according to claim 1, wherein the conductive layer has a thickness of 100 to 2000 Å.

8. The semiconductor device according to claim 1, wherein the metal oxide layer comprises an oxide layer having a dielectric constant of at least 3.9.

9. A method of fabricating a semiconductor device, comprising the steps of:
preparing a semiconductor substrate;
forming a silicon oxide layer on the semiconductor substrate;
forming a conductive layer on the silicon oxide layer; and
forming a metal oxide layer at an interface between the silicon oxide layer and the conductive layer.

10. A method of fabricating a semiconductor device according to claim 9, wherein the step of forming a silicon oxide layer further comprises forming a silicon dioxide layer having a thickness of 10 to 100 Å.

11. A method of fabricating a semiconductor device according to claim 9, wherein the step of forming the conductive layer further comprises forming a metal layer or a metal nitride layer.

12. A method of fabricating a semiconductor device according to claim 11, wherein the step of forming the metal layer further comprises forming a layer of at least one metal selected from a group consisting of tungsten (W), tantalum (Ta), titanium (Ti), and aluminum (Al).

13. A method of fabricating a semiconductor device according to claim 11, wherein the step of forming the metal nitride layer further comprises forming a layer of at least one metal nitride selected from a group consisting of tungsten nitride (WN), tantalum nitride (TaN), titanium nitride (TiN) and aluminum nitride (AlN).

14. A method of fabricating a semiconductor device according to claim 9, wherein the step of forming the conductive layer further comprises forming a conductive layer having a thickness of 100 to 2000 Å.

15. A method of fabricating a semiconductor device according to claim 9, wherein the step of forming a metal oxide layer at an interface between the silicon oxide layer and the conductive layer further comprises a thermal treatment, the thermal treatment being conducted at a temperature of 500 to 1000° C. and under an inert gas ambient.

16. A method of fabricating a semiconductor device according to claim 15, wherein the inert gas comprises at least one gas selected from a group consisting of nitrogen (N), argon (Ar), and helium (He).

17. A method of fabricating a semiconductor device according to claim 9, wherein the step of forming a metal oxide layer further comprises forming a metal oxide layer having a dielectric constant of at least 3.9.

18. A method of fabricating a semiconductor device according to claim 9, wherein the step of forming a metal oxide layer further comprises oxidizing a portion of the metal layer with oxygen atoms from the silicon oxide layer.

19. A method of fabricating a semiconductor device according to claim 9, wherein the silicon oxide layer is a gate insulator and the conductive layer is a gate electrode.
